(19) United States
(12) Patent Application Publication
(10) Pub. No.: US 2014/0085785 A1
(43) Pub. Date: Mar. 27, 2014

(54) ELECTRONIC DEVICE WITH RUBBER PADS

(71) Applicant: HON HAI PRECISION INDUSTRY CO., LTD., New Taipei (TW)

(72) Inventors: PO-CHING CHIANG, New Taipei (TW); LUN-FENG LIAO, New Taipei (TW); CHI-TSE SHIH, New Taipei (TW)

(21) Appl. No.: 13/920,061

(22) Filed: Jun. 17, 2013

(30) Foreign Application Priority Data
Sep. 24, 2012 (TW) 101135007

(51) Int. Cl. H05K 5/02

(52) U.S. Cl. CPC H05K 5/0217
USPC 361/679.01

(57) ABSTRACT

An electronic device comprises a chassis and a plurality of rubber pads mounted in a base panel of the chassis. A mounting hole is defined in the base panel. A protruding wall extends from an edge of the mounting hole towards an inner side of the base panel. A groove is defined in the protruding wall. Each of the plurality of rubber pads comprises a supporting wall and a mounting portion extending from an inner side of the supporting member. The mounting portion comprises a main body mounted in the mounting hole and a latch portion extending from the main body and extending through the groove for preventing the main body from disengaging from the mounting hole.

### BACKGROUND

1. Technical Field

The present disclosure relates to an electronic device with rubber pads.

2. Description of Related Art

An electronic device includes a base wall and a plurality of rubber pads mounted in the base wall. The plurality of rubber pads slightly protrudes from the base wall. When the electronic device is placed on a desk, the plurality of rubber pads is placed on the desk and supports the electronic device, which facilitates heat dissipation of the electronic device and prevents the base wall from directly rubbing the desk. However, it's inconvenient to mount or dismount the plurality of rubber pads.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled view of an embodiment of an electronic device with rubber pads.

FIG. 2 is an exploded view of one of the rubber pads and a base panel of the electronic device of FIG. 1.

FIG. 3 is similar to FIG. 2, but viewed from another aspect.

FIG. 4 is an assembled view of FIG. 2.

### DETAILED DESCRIPTION

The disclosure is illustrated by way of example and not by way of limitation in the figures of the accompanying drawings in which like references indicate similar elements. It should be noted thin references to “an” or “one” embodiment in this disclosure are not necessarily to the same embodiment, and such references mean “in least one.”

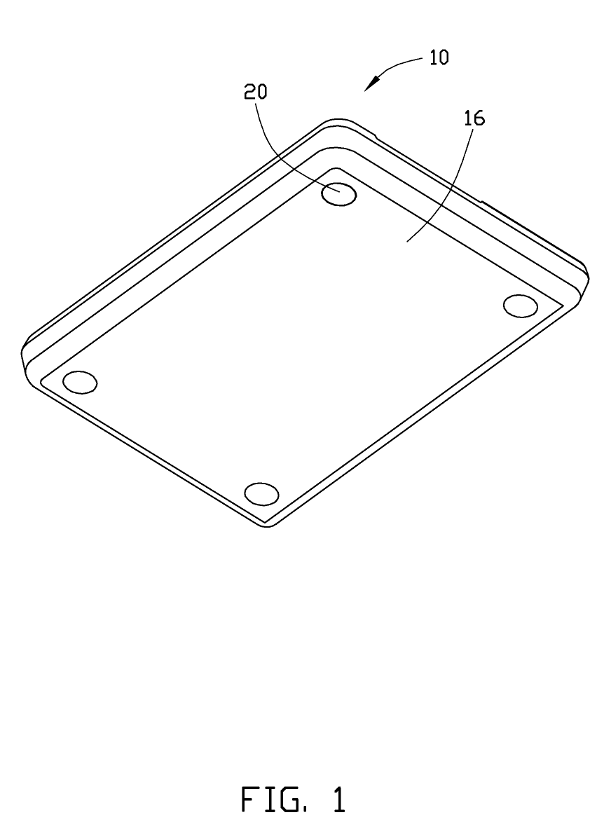

FIG. 1 shows an embodiment of an electronic device comprising a chassis 10 and four rubber pads 20 mounted in a base panel 16 of the chassis 10. The four rubber pads 20 are located adjacent to four corners of the base panel 16.

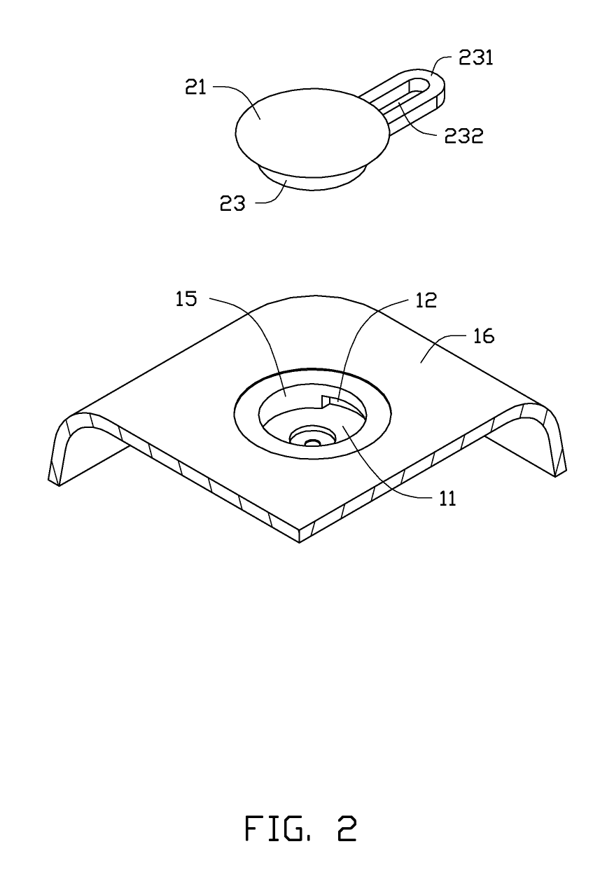

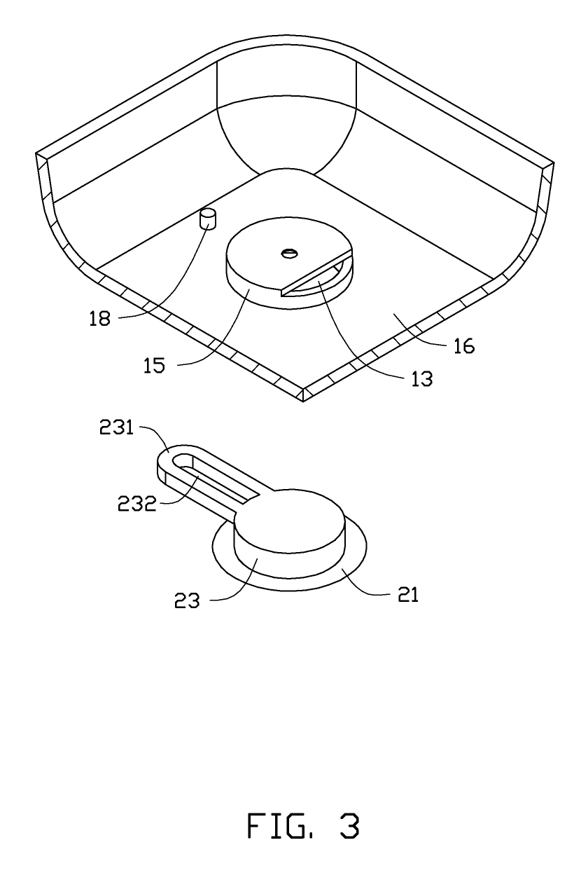

FIGS. 1 to 3 shows that a mounting hole 11 is defined at each corner of the base panel 16 for mounting each of the four rubber pads 20. A holding portion 15 extends from a circular edge of the mounting hole 11 and is located at an inner side of the base panel 16. The holding portion 15 includes a protruding wall 151 protruding substantially perpendicular from the circular edge of the mounting hole 11 and a resisting wall 153 connected to the protruding wall 151. The resisting wall 153 is substantially parallel to the base panel 16. A gap 13 is defined in the resisting wall 153 and communicating with the protruding wall 151. A groove 12 is defined in the protruding wall 151. The groove 12 and the gap 13 are located at opposite sides of the holding portion 15 relative to an axis of the holding portion 15. A post 18 extends substantially perpendicularly from an inner surface of the base panel 16. The post 18 is aligned with the groove 12.

Each of the four rubber pads 20 includes a supporting wall 21 and a mounting portion 23, extending from an inner side of the supporting wall 21. An outer surface of the supporting wall 21 protrudes outwardly and has an arc shape. The mounting portion 23 includes a cylindrical main portion 233 and a latch portion 231, extending from the cylindrical main portion 233. Axes of the cylindrical main portion 233 and the supporting wall 21 lie in the same line. The latch portion 231 extends from the cylindrical main portion 233 along a direction perpendicular to the axis of the supporting wall 21. A slot 2311 is defined in the latch portion 231. The latch portion 231 has a U shape. A diameter of the supporting wall 21 is greater than that of the mounting hole 11. A diameter of the cylindrical main portion 233 is substantially equal to that of the mounting hole 11.

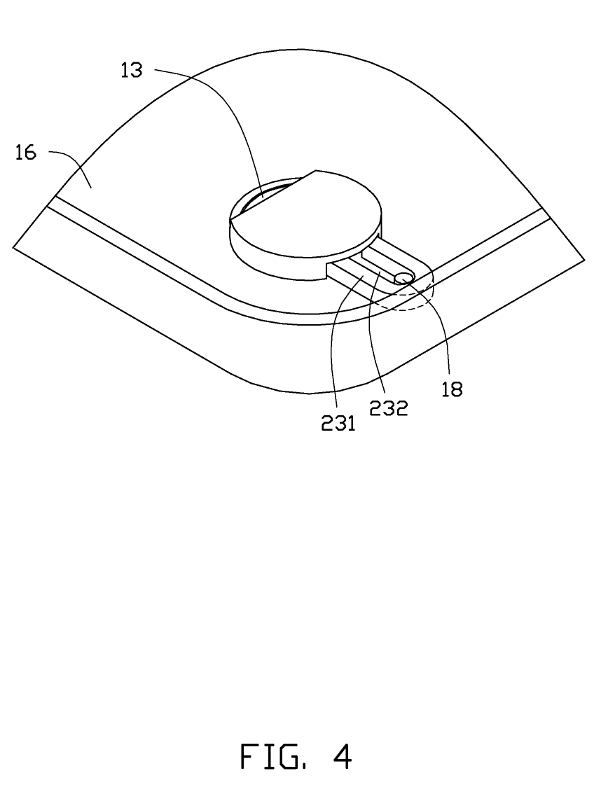

FIGS. 1 to 4 shows that in assembly, the latch portion 231 is aligned with the groove 12. The latch portion 231 is deformed and extends through the groove 12. The cylindrical main portion 233 is engaged with the mounting hole 11 and abuts the protruding wall 151 and the resisting wall 153. The supporting wall 21 covers the mounting hole 11 and abuts an outer surface of the base panel 16. The post 18 is engaged with a distal end of the slot 2311 and prevents the latch portion 231 disengaging away from the groove 12. Thus, each of the four rubber pads 20 can be easily mounted in the base panel 16.

In one embodiment, each of the four rubber pads 20 has flexibility and expandability. A portion of the cylindrical main portion 233 is slightly protruding and engages with the gap 13.

To detach each of the four rubber pads 20, the latch portion 231 is pulled to be disengaged from the post 18. The supporting wall 21 is pulled outwardly. The cylindrical main portion 233 is disengaged from the mounting hole 11. The latch portion 231 is pulled out from the groove 12. Thus, each of the four rubber pads 20 can be detached from the base panel 16.

It is to be understood, however, thin even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a chassis comprising a base panel; a mounting hole defined in the base panel and a protruding wall extending from an edge of the mounting hole towards an inner side of the base panel; and a groove defined in the protruding wall; and
a plurality of rubber pads mounted in the base panel and protruding outwardly from an outer surface of the base panel, each of the plurality of rubber pads comprising a supporting wall and a mounting portion extending from an inner side of the supporting wall, the mounting portion comprising a main body mounted in the mounting hole and a latch portion extending from the main body along a direction that is parallel to the base panel, and the latch portion extending through the groove for preventing the main body disengaging from the mounting hole.

2. The electronic device of claim 1, wherein the protruding wall is substantially perpendicular to the base panel.

3. The electronic device of claim 1, wherein the mounting hole is covered by the supporting wall, and the supporting wall abuts the base panel.

4. The electronic device of claim 1, wherein a diameter of the supporting wall is greater than that of the mounting hole, and a diameter of the main body is substantially equal to that of the mounting hole.

5. The electronic device of claim 1, wherein a post protrudes from the inner side of the base panel and is aligned with the groove, and the post is engaged with the latch portion.

6. The electronic device of claim 5, wherein a slot is defined in the latch portion, and the post is engaged with a distal end of the slot.

7. The electronic device of claim 6, wherein the latch portion has an L shape.

8. The electronic device of claim 1, wherein a resisting wall is connected to a circular edge of the protruding wall, and the main body is abut the protruding wall and the resisting wall.

9. The electronic device of claim 8, wherein a gap is defined in the resisting wall, and a portion of the main body is expanded and engaged with the gap.

10. The electronic device of claim 9, wherein the groove and the gap are located at opposite sides of the protruding wall.

11. An electronic device comprising:
a chassis comprising a base panel; a mounting hole defined in the base panel and a holding portion extending from an edge of the mounting hole towards an inner side of the base panel; and a groove defined in the holding portion; and
a plurality of rubber pads mounted in the base panel and protruding outwardly from an outer surface of the base panel, each of the plurality of rubber pads comprising a supporting wall, a main body extending from the supporting wall along a first direction, and a latch portion extending from the main body along a second direction that is substantially perpendicular to the base panel, the latch portion extending through the groove for preventing the main body disengaging from the mounting hole.

12. The electronic device of claim 1, wherein the holding portion comprises a protruding wall substantially perpendicularly extending from the edge of the mounting hole and a resisting wall connected to the protruding wall, the resisting wall is substantially perpendicular to the protruding wall, and the groove is defined in the protruding wall.

13. The electronic device of claim 12, wherein a gap is defined in the resisting wall, and a portion of the main body is expanded and engaged with the gap.

14. The electronic device of claim 13, wherein the groove and the gap are located at opposite sides of the holding portion relative to an axis of the holding portion.

15. The electronic device of claim 11, wherein the mounting hole is covered by the supporting wall, and the supporting wall abuts the base panel.

16. The electronic device of claim 11, wherein a diameter of the supporting wall is greater than that of the mounting hole, and a diameter of the main body is substantially equal to that of the mounting hole.

17. The electronic device of claim 11, wherein a post protrudes from the inner side of the base panel and is aligned with the groove, and the post is engaged with the latch portion.

18. The electronic device of claim 17, wherein a slot is defined in the latch portion, and the post is engaged with a distal end of the slot.

19. The electronic device of claim 18, wherein the latch portion has an L shape.

20. The electronic device of claim 11, wherein an outer surface of the supporting wall protrudes outwardly from the base panel and has an arc shape.
